(19) United States
(12) Patent Application Publication
(10) Pub. No.: US 2006/0151818 A1
(43) Pub. Date: Jul. 13, 2006

(54) Solid state imaging device and production method therefor

(76) Inventor: Yoshinori Toumiya, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 10/529,433

(22) PCT Filed: Sep. 18, 2003
(86) PCT No.: PCT/JP03/11915

§ 371 Date: Mar. 25, 2005

(30) Foreign Application Priority Data
Sep. 27, 2002 (JP) P2003-284352
Mar. 14, 2003 (JP) P2003-070750

(51) Int. Cl. H01L 31/062

(52) U.S. Cl. 257/294; 257/E31.121

(57) ABSTRACT

The present invention relates to a CMOS-type solid-state imaging device and a method for manufacturing thereof, and provides a solid-state imaging device capable of optimally condensing light by a single intra-layer lens and a manufacturing method capable of forming an intra-layer lens with high precision. The solid-state imaging device according to the present invention includes a plurality of wirings and a plurality of lenses above a light-receiving portion, in which at least one of the plurality of lenses is formed of a single intra-layer lens. The method for manufacturing the solid-state imaging device according to the present invention includes the processes of forming a concave surface or convex surface onto a first insulation layer with a first refractive index using a selective etching method and forming a second insulation layer with a second refractive index onto the concave surface or convex surface to form the intra-layer lens corresponding to the light-receiving portion.

### TECHNICAL FIELD

The present invention relates to a solid-state imaging device including an intra-layer lens and a method for manufacturing thereof.

### BACKGROUND ART

In a solid-state imaging device, when miniaturization of a light-receiving surface of each sensor portion advances and various kinds of films such as light shielding pattern. and wiring pattern are laminated, an incident light ratio deteriorates. Particularly, in a CMOS-type solid-state imaging device in which a number of light shielding patterns and wiring patterns are laminated, incident light is interrupted by wirings and the like to deteriorate the incident light ratio. As the countermeasure against the deterioration of the incident light ratio, there is known a method in which an intra-layer lens, that is, intra-layer condensing lens is provided between wiring layers corresponding to the upper part of the light-receiving surface to condense light onto a sensor portion without being interrupted by the wirings, so that a light condensing rate is improved. (refer to Japanese Published Patent application No. 2001-94085, for example).

Conventionally, an intra-layer condensing lens of a CMOS-type solid-state imaging device having multilayer wiring has been formed in the following manner. That is, after first wirings are formed in parallel on a substrate in which a sensor portion is formed with an insulation layer in between, a fluid film (what is called a reflow film) is formed across the whole surface thereof. As a fluid film, a BPSG (borophosphosilicate glass) film with a refractive index of approximately 1.4 to 1.46 is laminated by, for example, a CVD (Chemical Vapor Deposition) method. Next, this BPSG film is subjected to heat treatment of 800° C. to 950° C. to reflow. By the reflow processing using a stepped difference of the shielding pattern, the BPSG film is formed into a cylindrical concave shape to be in parallel with the first wiring. Next, a silicon nitride film with a refractive index of approximately 2.0 is laminated thereon by a plasma CVD method, and then this silicon nitride film is planarized by a CMP (Chemical Mechanical Polishing) method. As a result, a first cylindrical intra-layer condensing lens extending in one direction is formed of the concave-shaped BPSG film with a small refractive index and the planarized silicon nitride with a large refractive index. Next, after second wirings are formed in parallel with a sensor portion in between on a film constituting the first cylindrical intra-layer condensing lens to perpendicularly intersect the first wiring, a cylindrical convex-shaped BPSG film is similarly formed along the second wiring and a planarized silicon nitride film is formed thereon to form a second cylindrical intra-layer condensing lens. These two first and second cylindrical intra-layer condensing lenses that intersect each other form intra-layer condensing lenses that are separated into units by respective sensor portions.

Hereupon, with respect to the shape of the intra-layer condensing lens using the above described fluid film, the height, position and curvature of the lens are decided in a self-aligning manner by the distance and height of underlaid light shielding films or wiring. Therefore, it is difficult to obtain the shape of the intra-layer condensing lens that is necessary for optimum condensing of light.

In addition, since heat treatment at a high temperature of 800° C. to 950° C. is necessary in the reflow process of the fluid film, it has been impossible to use Al that has been reliably used for wiring.

### DISCLOSURE OF THE INVENTION

The present invention provides a solid-state imaging device including a single intra-layer lens with high precision capable of optimum condensing of light and a method for manufacturing thereof.

A solid-state imaging device according to the present invention includes: a plurality of pixels each including a light-receiving portion, a wiring layer including a plurality of wirings and a plurality of lenses which are formed above the light-receiving portions, wherein at least one of the plurality of lenses is an intra-layer lens including a first layer with a concave portion formed by etching and a second layer formed to bury the concave portion.

The wiring layer includes at least a first wiring and a second wiring formed on both sides of the light-receiving portion, and the first wiring and second wiring are formed differently with respect to distance from the light-receiving portion. The intra-layer lens is positioned between the first wiring and second wiring.

The first wiring and second wiring can integrally be formed to be connected to a predetermined voltage source. A pixel has a charge readout transistor and a planarizing film that covers a gate electrode of the charge readout transistor to be planarized, with a plurality of wirings formed above the planarizing film. Accordingly, the first layer can be formed of an insulation layer constituting a wiring layer formed by directly covering the plurality of wirings. Accordingly, the first layer can be formed of the insulation layer formed on the wiring layer. In a pixel farther away from the center of an imaging region, the intra-layer lens can be formed having the center thereof biased from above the center of the light-receiving portion to the center side of the imaging region. At least one of the plurality of lenses can be made an on-chip lens formed above the intra-layer lens.

A Solid-state imaging device according to the present invention includes a plurality of pixels each including a light-receiving portion, a wiring layer including a plurality of wirings and a plurality of lenses which are formed above the light-receiving portions, wherein at least one of the lenses is an intra-layer lens including a first layer with a convex portion formed by etching and a second layer formed to cover the convex portion.

The wiring layer includes at least a first wiring and a second wiring formed on both sides of the light-receiving portion, and the first wiring and second wiring are formed differently with respect to distance from the light-receiving portion. The intra-layer lens is positioned between the first wiring and second wiring. A third layer can be formed between the first layer and second layer to cover the convex portion.

According to a solid-state imaging device of the present invention, in a CMOS-type solid-state imaging device, since an intra-layer lens (concave lens) is formed such that a second layer buries a concave portion formed by etching a first layer with respect to respective light-receiving portions, it is possible to dispose the intra-lens at an appropriate position without depending on the unevenness of the wiring. Accordingly, incident light can be optimally condensed on the light-receiving portion. Being a single intra-lens makes the structure of the intra-lens simplified. In the case where the first wiring and second wiring are formed on both sides of the light-receiving portion, having difference with respect to distance from the light-receiving portion, there is a high possibility that the intra-lens can not be disposed at a required position with respect to the light-receiving portion when the intra-lens is formed and used depending on the unevenness of the wirings. According to the present invention, however, the intra-layer lens (concave lens) can be disposed at a required position without depending on the wirings even in the case of including wirings having difference with respect to distance from the light-receiving portion. In the case where wirings are disposed such that the first wiring and second wiring are integrally formed to be connected to a required voltage source, the intra-layer lens can also be disposed at a required position without being affected by the wirings. Even in a solid-state imaging device in which a gate electrode of a readout transistor is lopsidedly formed with respect to the light-receiving portion, the intra-layer lens can be disposed at a required position without depending on the unevenness of the gate electrode.

When an intra-layer lens is formed after providing a concave portion for an insulation layer that constitutes the wiring layer, the intra-layer lens can be formed at a position close to the light-receiving portion. Therefore, the thickness above the light-receiving portion can be reduced to make a solid-state imaging device small-sized. On making a concave portion in an insulation layer formed separately from the wiring layer to form an intra-layer lens, when condensed light is led to the light-receiving portion passing by the side of the wiring layer, refraction on the interface of the insulation layer separately formed from the wiring layer can also be used. An intra-lens can be disposed according to the bias of an inclination of incident light within an imaging region without depending on the unevenness of wirings included in the wiring layer. When an intra-layer is formed in a pixel farther away from the center of an imaging region with the center thereof formed having a bias to the center side of an imaging region from the center of a light-receiving portion, shading due to oblique light can be improved to make pupil correction possible. With making at least one of a plurality of lenses into an on-chip lens formed above the intra-layer lens, incident light can be condensed onto the light-receiving portion by cooperative work of the on-chip lens and intra-layer lens.

According to a solid-state imaging device of the present invention, in a CMOS-type solid-state imaging device, with respect to a light-receiving portion since an intra-layer lens (convex lens) is formed such that a concave portion formed after etching a first layer is buried with a second layer, the intra-layer lens can be disposed at an appropriate position without depending on the unevenness of wirings. Accordingly, incident light can optimally be condensed onto the light-receiving portion. Being a single intra-lens makes the structure of the intra-lens simplified. In a case where the first wiring and second wiring are formed on both sides of the light-receiving portion, having difference with respect to distance from the light-receiving portion, there is a high possibility that the intra-lens can not be disposed at a required position with respect to the light-receiving portion when the intra-lens is formed and used depending on the unevenness of the wirings. According to the present invention, however, the intra-layer lens (convex lens) can be disposed at a required position even in the case of including wirings having difference with respect to distance from the light-receiving portion without depending on the wirings. When a third layer is formed between the first and second layers to cover a convex portion, the convex shape of the intra-lens can be smoothly formed.

A method for manufacturing a solid-state imaging device according to the present invention includes the processes of: forming a plurality of light-receiving portions on the surface of a substrate; forming wirings on both sides of the light-receiving portion; forming a first insulation layer with a first refractive index; etching the first insulation layer by using an etching mask to form a concave portion above the light-receiving portion; and forming a second insulation layer with a second refractive index to bury the concave portion. Prior to the process of forming the wirings, this manufacturing method can further includes the processes of: forming a charge readout transistor; forming a gate electrode for operating the charge readout transistor; and forming a planarizing film to cover the gate electrode to be planarized, so that the wirings and the concave portion can be formed above the planarizing film.

According to the method for manufacturing a solid-state imaging device of the present invention, a first insulation layer with a first refractive index is etched to form a concave portion and a second insulation layer with a second refractive index is formed to bury the concave portion corresponding to respective light-receiving portions, so that an intra-lens of a concave lens can be formed at an appropriate position without depending on the unevenness of wirings. Accordingly, a CMOS-type solid-state imaging device can be manufactured in which incident light can optimally be condensed onto the light-receiving portions. Prior to the process of forming the wirings, the manufacturing method includes the processes of: forming a charge readout transistor, forming a gate electrode thereof, and forming a planarizing film to cover the gate electrode to be planarized; and by forming wirings and a concave portion above the planarizing film, an intra-layer lens of a concave lens can be formed at a position close to the light-receiving portions. Consequently, the thickness of the layer above the light-receiving portions is reduced to manufacture a small-sized solid-state imaging device.

A method for manufacturing a solid-state imaging device according to the present invention includes the processes of: forming a plurality of light-receiving portions on the surface of a substrate; forming wirings on both sides of the light-receiving portions; forming a first insulation layer with a first refractive index; forming a reflow film with a convex surface by reflow processing on the first insulation layer at a position corresponding to the light-receiving sensor portions; transferring the convex surface onto the first insulation layer by etching back the first insulation layer with the reflow film and forming a second insulation layer with a second refractive index on the first insulation layer. In the manufacturing method, prior to the process of forming the second insulation layer, a third insulation layer can be formed to cover the convex surface of the first insulation layer.

According to the method for manufacturing a solid-state imaging device of the present invention, a reflow film with a convex surface is formed on a first insulation layer with a first refractive index corresponding to each of the light-receiving portions, the first insulation layer with the reflow film is etched back to transfer the convex surface to the first insulation layer, and a second insulation layer with a second refractive index is formed on the first insulation layer, so that an intra-layer lens of a convex lens can be formed at an appropriate position without depending on the unevenness of wirings. Consequently, a CMOS-type solid-state imaging device can be manufactured in which incident light is optimally condensed onto the light-receiving portions. When a third insulation layer is formed to cover the convex surface of the first insulation layer prior to the process of forming the second insulation layer, the intra-lens can be formed of a convex lens shape.

A solid-state imaging device according to the present invention includes a plurality of pixels made of a light-receiving sensor portion and MOS transistor, and a single intra-layer condensing lens is formed corresponding to each of the light-receiving sensor portions.

This solid-state imaging device can be constructed such that part of uppermost layer wirings formed above the light-receiving sensor portion are disposed on both sides of the light-receiving sensor portion. The intra-layer condensing lens can be formed, whose center is biased from the center of the light-receiving sensor portion to the center of the imaging region at the farther periphery of the imaging region.

This solid-state imaging device can be constructed such that part of uppermost layer wirings positioned on both sides of the light-receiving sensor portion are asymmetrically disposed with respect to each light-receiving sensor portion, and the intra-layer condensing lens is formed without being affected by the asymmetric wirings.

Metal materials including Al can be used to form the wirings.

According to a solid-state imaging device of the present invention, in a CMOS-type solid-state imaging device, a single intra-layer condensing lens can be provided corresponding to each light-receiving sensor portion. Accordingly, even in a structure in which a number of light shielding patterns, wiring patterns and the like are superimposed, incident light can optimally be condensed onto the light-receiving sensor portion. In addition, being a single intra-layer condensing lens makes the structure of the intra-layer condensing lens simplified. Further, with respect to an intra-layer condensing lens on the periphery of an imaging region, when the center of the lens is formed to be biased to the center side of the imaging region from the center of the light-receiving sensor portion at the farther periphery, shading due to oblique light can be improved. Since the wirings of the CMOS-type solid-state imaging device can be formed of metal materials including Al, reliability as the wiring can be obtained.

When part of uppermost layer wirings disposed on both sides of the light-receiving sensor portion are asymmetrically disposed with respect to the light-receiving sensor portion, and the intra-layer condensing lens is formed without being affected by the asymmetrical wirings, the single intra-layer condensing lens can be formed without paying attention to the disposition of wirings and light shielding films. Consequently, the CMOS-type solid-state imaging device can be provided in which a light condensing rate is improved by a high precision single intra-layer condensing lens and high reliability is obtained.

A method for manufacturing a solid-state imaging device according to the present invention includes the processes of: forming wirings on a semi-conductor region in which a plurality of pixels each including a light-receiving sensor portion and MOS transistor are arranged through an insulation layer with each light-receiving sensor portion in between; forming a first insulation layer with a first refractive index across the whole surface thereof; with an etching mask, selectively removing the first insulation layer by way of isotropic etching at a position corresponding to the light-receiving sensor portion to form a concave portion corresponding to each light-receiving sensor portion; forming a second insulation layer with a second refractive index across the whole surface thereof including the concave portion; and planarizing the second insulation layer and leaving the second insulation layer within the concave portion to form a single intra-layer condensing lens with the first and second insulation layers.

According to the method for manufacturing a solid-state imaging device of the present invention, a concave portion of a first insulation layer is subjected to isotropic etching through a resist mask and later, a second insulation layer is formed to constitute an intra-layer condensing lens. Accordingly, a single intra-layer condensing lens can easily be formed in a CMOS-type solid-state imaging device. Since a high temperature reflow processing is not required, wirings can be formed of metal materials including Al. The shape of the intra-layer condensing lens (the height, position, curvature and the like of lens) can be easily adjusted by changing an opening pattern of a resist mask, etching conditions and the like. Further, only by changing the opening pattern of the resist mask, the center of the intra-layer condensing lens can be biased to the center side of an imaging region from the center of a light-receiving portion. As a result, the pupil correction method using the biased-lens can be adopted as the countermeasure against shading due to oblique light on the periphery of the imaging region. As described above, according to the manufacturing method of the present invention, an intra-layer condensing lens can be formed in the CMOS-type solid-state imaging device with high precision.

A method for manufacturing a solid-state imaging device according to the present invention includes the processes of: forming wirings on a semi-conductor region, in which a plurality of pixels each including a light-receiving sensor portion and MOS transistor are arranged, through an insulation layer with the light-receiving sensor portion in between; forming a first insulation layer with a first refractive index across the whole surface thereof; forming a reflow film whose surface is convex-shaped by reflow processing at a position corresponding to each light-receiving sensor portion on the first insulation layer; etching back the first insulation layer with the reflow film and transferring the convex surface onto the first insulation layer; and forming a planarizing film with a second refractive index on the first insulation layer to form a single intra-layer lens of the first insulation layer and the planarizing film.

According to the method for manufacturing a solid-state imaging device of the present invention, a reflow film having a convex-shaped surface is formed through reflow processing on a first insulation layer with a first refractive index at a position corresponding to each of light-receiving sensor portions, and the first insulation layer including the reflow film is subjected to etching back, so that the convex-shaped surface is transferred to the first insulation layer. Since an intra-layer condensing lens of a convex lens is formed after forming a planarizing film (insulation layer) having a second refractive index on the first insulation layer, a single intra-layer condensing lens can easily be formed. Particularly, in the case where part of the uppermost layer wirings are disposed in parallel on both sides of the light-receiving sensor portion and are disposed symmetrically with respect to the light-receiving sensor portion, the intra-layer condensing lens can be formed with respect to each light-receiving sensor portion without being affected by underlaid wirings. The shape of the intra-layer condensing lens (the height, position, curvature of the lens) can easily be adjusted by changing a photo resist pattern of a reflow film, etching conditions and the like. Only by changing the pattern of the resist mask, the center of the intra-layer condensing lens can be biased to the center side of an imaging region from the center of the light-receiving sensor portion. Accordingly, the pupil correction method using the biased-lens can be adopted as the countermeasure against shading due to oblique light on the periphery of the imaging region. As described above, according to the manufacturing method of the present invention, an intra-layer condensing lens can be formed with precision in the CMOS-type solid-state imaging device.

### BREIF DESCRIPTION OF DRAWINGS

FIG. 1 is an equivalent circuit diagram of a pixel portion showing an embodiment of a CMOS-type solid-state imaging device according to the present invention;

FIG. 2 is a plan view of the pixel portion showing an embodiment of the CMOS-type solid-state imaging device according to the present invention;

FIG. 3 is a sectional view on A-A line of FIG. 2;

FIG. 4 is a sectional view of the pixel portion on the periphery of an imaging region, showing an embodiment of the CMOS-type solid-state imaging device according to the present invention;

FIGS. 5A to 5C are (first) manufacturing process diagrams showing an embodiment of a method for manufacturing the CMOS-type solid-state imaging device according to the present invention;

FIGS. 6A to 6C are (second) manufacturing process diagrams showing an embodiment of the method for manufacturing the CMOS-type solid-state imaging device according to the present invention;

FIGS. 7A to 7C are (first) manufacturing process diagrams showing another embodiment of the method for manufacturing the CMOS-type solid-state imaging device according to the present invention;

FIGS. 8A to 8C are (second) manufacturing process diagrams showing another embodiment of the method for manufacturing the CMOS-type solid-state imaging device according to the present invention;

FIGS. 9A and 9B are (third) manufacturing process diagrams showing another embodiment of the method for manufacturing the CMOS-type solid-state imaging device according to the present invention;

FIG. 10 is a sectional view of the CMOS-type solid-state imaging device showing another embodiment of the present invention;

FIGS. 11A to 11C are (first) manufacturing process diagrams showing another embodiment of the method for manufacturing the CMOS-type solid-state imaging device according to the present invention;

FIGS. 12A to 12C are (second) manufacturing process diagrams showing another embodiment of the method for manufacturing the CMOS-type solid-state imaging device according to the present invention;

FIGS. 13A and 13B are (third) manufacturing process diagrams showing another embodiment of the method for manufacturing the CMOS-type solid-state imaging device according to the present invention;

FIGS. 14A and 14B are (forth) manufacturing process diagrams showing another embodiment of the method for manufacturing the CMOS-type solid-state imaging device according to the present invention; and

FIG. 15 is a (fifth) manufacturing process diagram showing another embodiment of the method for manufacturing the CMOS-type solid-state imaging device according to the present invention.

### BEST MODE FOR CARRYING OUT THE INVENTION

Hereinafter, an embodiment of the present invention will be explained referring to drawings.

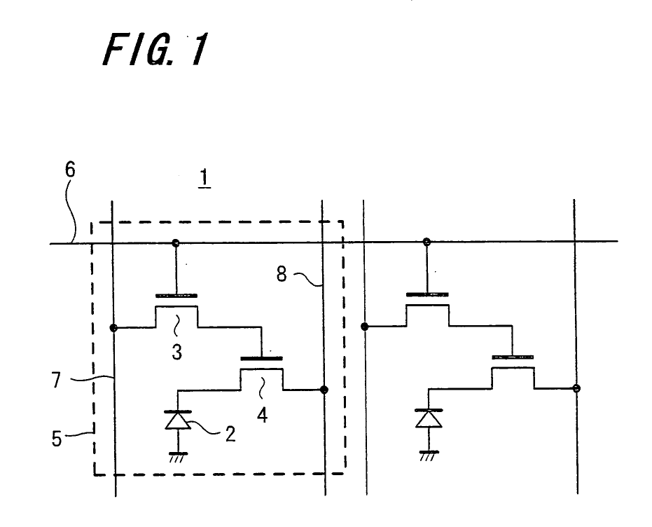

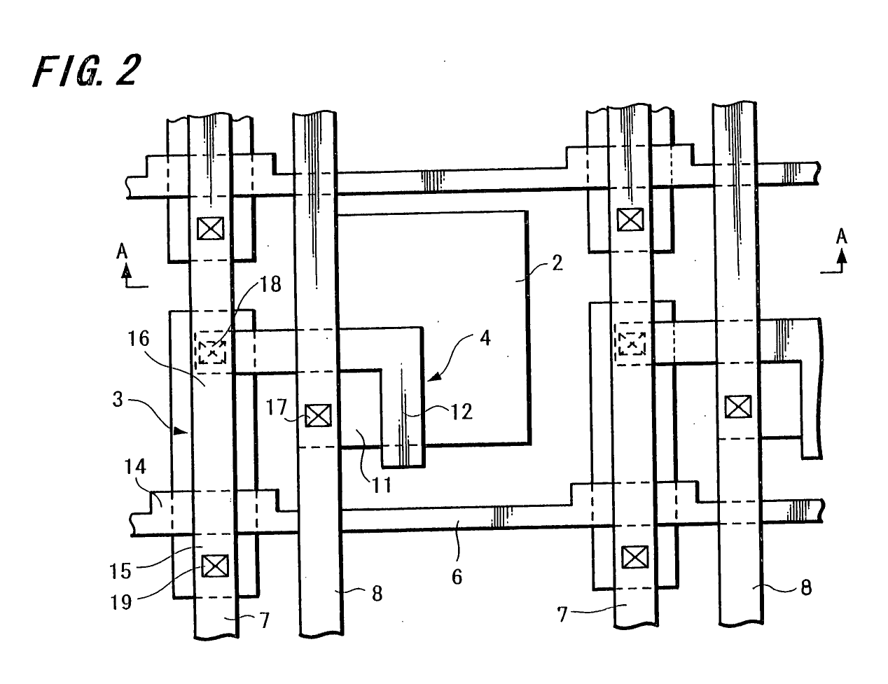

FIGS. 1 and 2 show the relevant part of an embodiment of a solid-state imaging device according to the present invention, that is, the structure of a pixel portion. The solid-state imaging device according to this embodiment is what is called a CMOS-type solid-state imaging device. As shown in FIG. 1, a solid-state imaging device 1 has an imaging region including a plurality of unit pixels 5 which are disposed in a matrix state and each of which includes a light-receiving portion for conducting photoelectric conversion, that is, a light-receiving sensor portion (namely, photodiode) 2, a vertical selection switch element (MOS transistor) 3 to select a pixel, and a readout switch element (MOS transistor) 4. One main electrode of the readout switch element 4 is connected to the light-receiving sensor portion 2, and a control electrode (what is called a gate electrode) of the readout switch element 4 is connected to an electrode of the vertical selection switch element 3. A vertical selection line 6 is connected to the control electrode (what is called a gate electrode) of the vertical selection switch element 3 in each row, and a vertical scanning pulse output from a vertical scanning circuit (not shown) is supplied to the vertical selection line 6. The other main electrode of the vertical selection switch element 3 in each column is connected to a readout pulse line 7, and a readout pulse output from a horizontal scanning circuit (not shown) is supplied to the readout pulse line 7. The other main electrode of the readout switch element 4 in each column is connected to a vertical signal line 8. Further, a vertical switch element (not shown) formed of the MOS transistor is connected between the vertical signal line 8 and the horizontal signal line (not shown), and a horizontal scanning pulse output from the horizontal scanning circuit is supplied to the control electrode of the horizontal switch element.

FIG. 2 shows a plan structure of the relevant part of the imaging region corresponding to the equivalent circuit of FIG. 1. The readout pulse line 7 and the vertical signal line 8 are formed in the vertical direction, and the vertical selection line 6 is formed in the horizontal direction to cross the pulse line 7 and vertical signal line 8 at right angles. An L-shaped gate electrode 12 is formed between the light-receiving sensor portion 2 and a semiconductor region 11 through a gate insulation layer, and the readout switch element 4 is formed of the light-receiving sensor portion 2, semiconductor region 11 and gate electrode 12. The vertical selection switch element 3 is formed of a gate electrode 14 that is integrated with the vertical selection line 6 and both the regions 15, 16 that become a source region and a drain region respectively with the gate electrode 14 in between. A numeral 17 denotes a contact portion between a semi-conductor region 11 constituting the readout switch element 4 and vertical signal line, a numeral 18 denotes a contact portion between the gate electrode 12 of the readout switch element 4 and the other region 16 of the vertical selection switch element 3 and a numeral 19 denotes a contact portion between one region 15 of the vertical selection switch element 3 and readout pulse line 7, respectively.

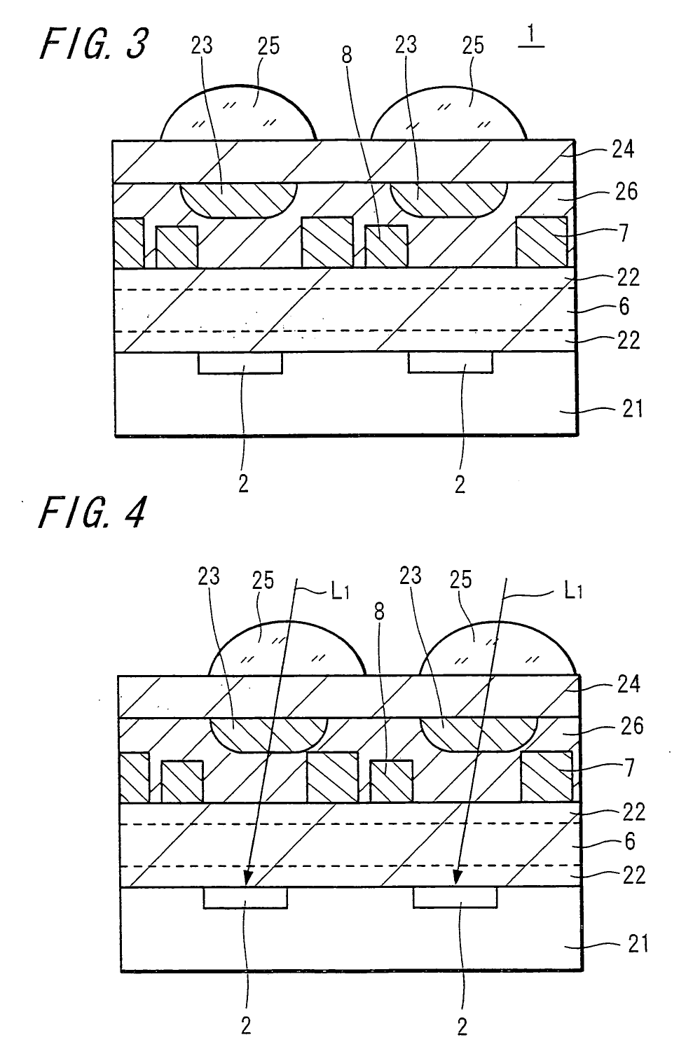

FIG. 3 shows a section structure on A-A line of FIG. 2. In this embodiment, on a semiconductor substrate 21 specifically formed with the light-receiving sensor portion 2, vertical selection switch 3 (not shown) and readout switch element 4; the vertical selection line 6 of for example a first layer wiring through an intra-layer insulation layer 22; the readout pulse line 7 of for example a second layer wiring; and the vertical signal line 8 are formed; further, thereupon, single intra-layer lenses, that is, intra-layer condensing lenses (concave lens, convex lens) 23 are formed between wirings groups adjacent to each other (the readout pulse line 7 and vertical signal line 8) so as to correspond to the position of each light-receiving sensor portion 2. A color filter 24 is formed above the intra-layer lens 23, and further, thereupon, at a position corresponding to each light-receiving sensor portion 2, that is, the position corresponding to each intra-layer condensing lens 23, is formed an on-chip micro-lens 25. In this embodiment, second layer wirings 7 and 8 of the uppermost layer, which are disposed on both sides of the light-receiving sensor portion 2 are designed to be asymmetrical with respect to the light-receiving sensor portion 2. Accordingly, the second layer wiring 8 of a pixel and the second layer wiring 7 of an adjacent pixel are disposed at positions having difference with respect to distance from the light-receiving sensor portion.

Here, the lower side intra-layer insulation layer 22 covers the unevenness of the gate electrode and the like of the readout transistor 4 to read out charges accumulated in the light-receiving sensor portion 2 and functions as a planarizing film. Further, a first wiring layer is formed including the vertical selection line 6 of the first-layer wiring and the intra-layer insulation layer 22 insulating this wiring. A second wiring layer is formed including the readout pulse line 7 and vertical signal line 8 of the second-layer wirings and an insulation layer 26 insulating those wirings to form the intra-layer condensing lens 23.

FIG. 4 shows a pixel portion on the periphery of the imaging region. In this embodiment, as a countermeasure against shading by oblique light L₁ incident on pixels of the peripheral side, the intra-layer condensing lens 23 is formed such that the center of the lens is biased to the center side of the imaging region from the center of the light-receiving sensor portion 2 with respect to the intra-layer condensing lens 23 father on the periphery of the imaging region.

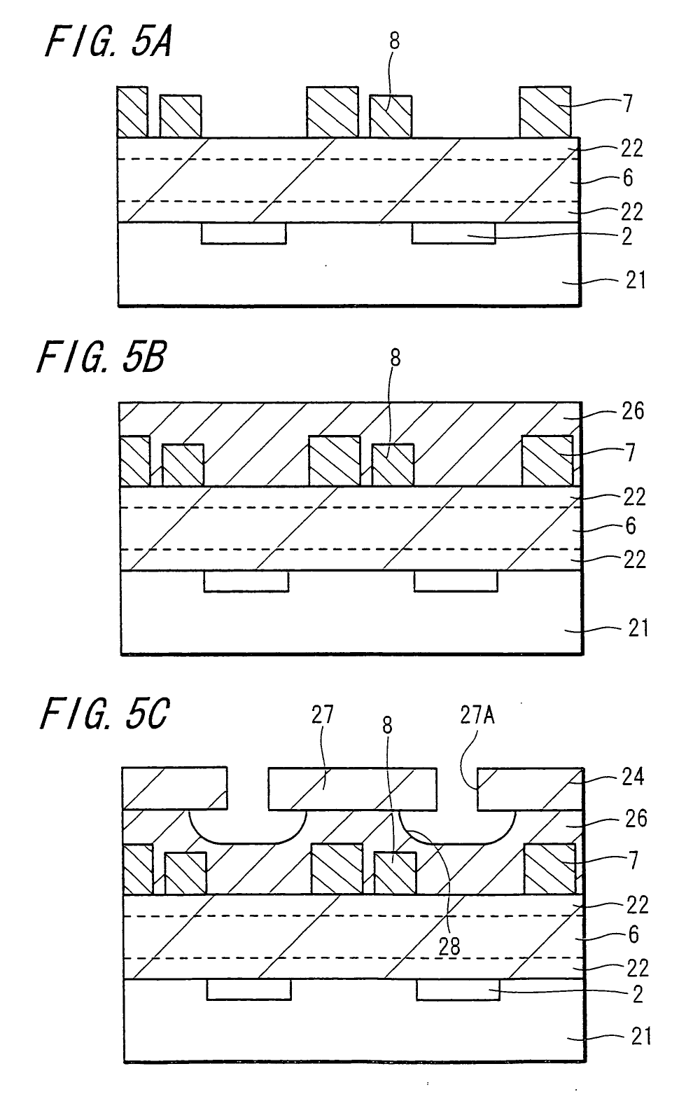

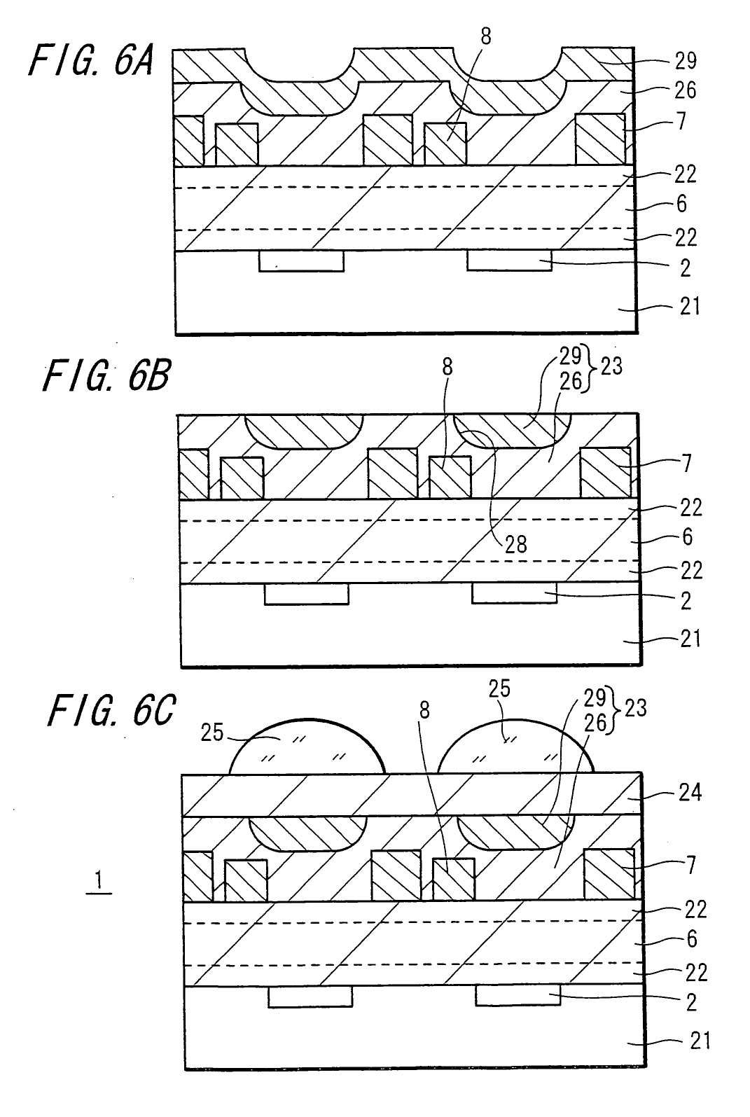

Next, an embodiment of the method for manufacturing the CMOS-type solid-state imaging device according to the above-described embodiment will be explained with reference to FIGS. 5 and 6.

First, as shown in FIG. 5A, after the light-receiving sensor portion 2 constituting what is called a CMOS sensor, the vertical selection switch element 3 and the readout switch element 4 (not shown) are formed on the semiconductor substrate 21, a light shielding film and wirings that are insulated from each other are formed through the intra-layer insulation layer 22, in this embodiment, the vertical selection line 6 to be a first-layer wiring extending in one direction on both sides of the light-receiving sensor portion 2, and the readout pulse line 7 and the vertical signal line 8 on both sides of the light-receiving sensor portion 2 to be a second-layer wiring group extending in another direction crossing the above-described one direction at right angles are formed. Those vertical selection line 6, readout pulse line 7 and vertical signal line 8 are formed of metal materials including Al, in this embodiment, Al. In this embodiment, as shown in FIG. 2, the readout pulse line 7 and vertical signal line 8 to be the second-layer wiring group are asymmetrically formed with respect to the light-receiving sensor portion 2. Accordingly, the vertical signal line 8 of a pixel and the readout pulse line 7 of an adjacent pixel are disposed at positions having difference with respect to distance from the light-receiving sensor portion 2.

Next, as shown in FIG. 5B, a first insulation layer 26 with a first refractive index is formed across the whole surface including the readout pulse line 7 and vertical signal line 8, and then the first insulation layer 26 is planarized. For example, the first insulation layer 26 can be formed by laminating a low temperature CVD film by high density plasma CVD, plasma TEOS or the like, for example, a BPSG (borophosphosilicate glass) film. A BPSG film has, as described above, a refractive index of approximately 1.40 to 1.46. The first insulation layer 26 can be planarized by a CMP (Chemical Mechanical Polishing) method.

Next, as shown in FIG. 5C, a photo-resist film is formed on the first insulation layer 26, which is then subjected to patterning such that an opening 27A is formed at a position corresponding to the light-receiving sensor portion 2 to form a resist mask 27. By way of isotropic-etching through the resist mask 27, the first insulation layer 26 is selectively etched and removed. Accordingly, a concave portion 28 corresponding to each light-receiving sensor portion 2 is formed in the first insulation layer 26 to form the intra-layer condensing lens. The position, size, curvature, depth and the like of the concave portion 28 are arbitrarily controlled by an opening 27A of the resist mask 27, etching time and the like.

Next, after the resist mask 27 is removed, as shown in FIG. 6A, a second insulation layer 29 with a second refractive index is formed across the whole surface to bury the concave portion 28. The second insulation layer 29 can be formed by laminating a silicon nitride (P—SiN) film by a plasma CVD method, for example. This silicon nitride film has a refractive index of approximately 2.0.

Next, as shown in FIG. 6B, the second insulation layer 29 is planarized by etching back or the like. As a result, the single intra-layer condensing lens (concave lens) 23 including the first insulation layer 26 with a small refractive index and the second insulation layer 29 with a large refractive index is formed. In this intra-layer condensing lens 23, On the upper interface of the planarized second insulation layer 29 and the upper interface of the not-planarized first insulation layer 26 light is refracted in the direction of condensing, in conjunction with the relative relations between the refractive indices thereof.

Next, as shown in FIG. 6C, the color filter 24 is formed on the above-described planarized upper surface, and further, the on-chip micro-lens 25 is formed on the color filter 24, so that the aimed CMOS-type solid-state imaging device 1 is obtained.

According to the CMOS-type solid-state imaging device 1 of the present invention, a single intra-layer condensing lens, that is, the concave lens 23 in this embodiment corresponding to each light-receiving sensor portion 2 is provided, so that incident light can be optimally condensed on the light-receiving sensor portion 2 even in the structure including a number of light shielding patterns, wiring patterns and the like. Also in the case where the uppermost layer wirings 7 and 8 are disposed on both sides of the light-receiving sensor portion 2, since each light-receiving sensor portion has a single intra-layer condensing lens, the light condensing rate can be improved. In addition, being a single intra-layer condensing lens 23 without combining two cylindrical intra-layer condensing lenses makes the structure thereof simplified. Since the wirings 6, 7 and 8 are formed of metal materials including Al, reliability of the wirings 6, 7 and 8 can be obtained. Further, since the intra-layer condensing lens 23 on the periphery of the imaging region is formed to be biased to the center side of the imaging region from the center of the light-receiving sensor portion 2 at the farther periphery of the imaging region, shading due to oblique light can be improved. Since the wirings 7 and 8 are asymmetrically disposed with respect to the light-receiving sensor portion 2 and the intra-layer condensing lens 23 is formed without being affected by underlaid wirings, light can be received favorably. Consequently, the light condensing rate is improved with the single intra-layer condensing lens with high precision and the CMOS-type solid-state imaging device which has high reliability can be provided.

According to the method for manufacturing the CMOS-type imaging device of this embodiment, since the concave portion 28 of the first insulation layer 26 is subjected to isotropic-etching through the resist mask 27 and then the second insulation layer 29 is provided to form the intra-layer condensing lens 23, the single intra-layer condensing lens can be easily formed. Particularly, in the case where part of the uppermost layer wirings are disposed in parallel on both sides of the light-receiving sensor portion 2 and disposed asymmetrically with respect thereto, the intra-layer condensing lens 23 can be formed in each light-receiving sensor portion without being affected by underlaid wirings. The shape (the height, position, curvature and the like) of the intra-layer condensing lens 23 can easily be adjusted by changing the pattern (what is called an opening pattern) of an opening 27A of the resist mask 27, etching conditions and the like. Since high temperature reflow processing is not required, wirings 6, 7 and 8 can be formed of metal materials including Al. In addition, by changing the opening pattern of the resist mask 27, the center of the intra-layer condensing lens 23 can simply be biased to the center side of the imaging region from the center of the light-receiving sensor portion 2. Accordingly, as the countermeasure against shading due to oblique light on the periphery of the imaging region, what is called a biased-lens pupil correction method can be applied. As described above, according to the manufacturing method of this embodiment, the intra-layer condensing lens 23 can be formed with high precision in the CMOS-type solid-state imaging device.

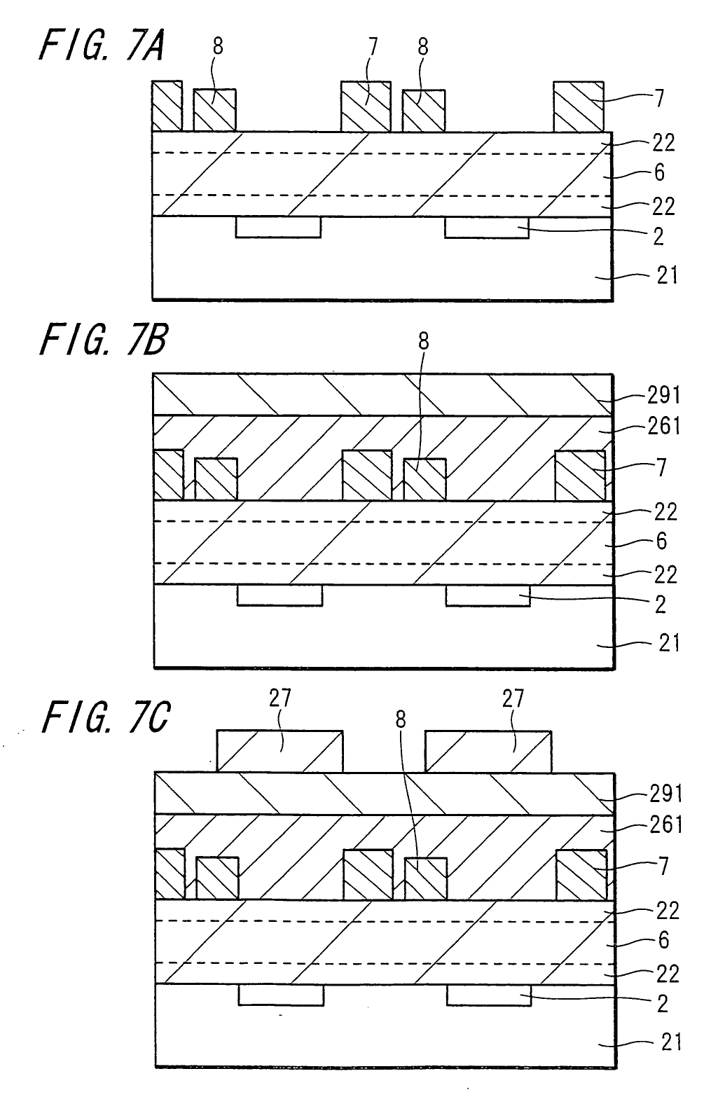

Next, another embodiment of the CMOS-type solid-state imaging device and the method for manufacturing thereof will be explained with reference to FIGS. 7, 8 and 9.

First, as shown in FIG. 7A and as described above, after the light-receiving sensor portion 2 constituting what is called a CMOS sensor, vertical selection switch element 3 and readout switch element 4 (not shown) are formed on the semiconductor substrate 21, through the intra-layer insulation layer 22 are formed a light shielding film and wirings insulated from each other, in this embodiment, which are the vertical selection line 6 to be a first-layer wiring extending in one direction on both sides of the light-receiving sensor portion 2 and on both sides of the light-receiving sensor portion 2 are formed the readout pulse line 7 and the vertical signal line 8 to be a second-layer wirings group extending in another direction crossing the above-described one direction at right angles. Those vertical selection line 6, readout pulse line 7 and vertical signal line 8 are formed of metal materials including Al, in this embodiment, Al. In this embodiment, as shown in FIG. 2, the readout pulse line 7 and vertical signal line 8 are asymmetrically formed at positions with respect to the light-receiving sensor portion 2. Accordingly, the vertical signal line 8 of a pixel and the readout pulse line 7 of an adjacent pixel are disposed at positions having difference with respect to distance from the light-receiving sensor portion 2.

Next, as shown in FIG. 7B, a first planarizing film (insulation layer) 261 is formed across the whole surface including the readout pulse line 7 and vertical signal line 8. Then, a first insulation layer 291 with a first refractive index is formed. For example, the first insulation layer 291 can be formed by laminating a low temperature CVD film of such as a high density plasma CVD or plasma TEOS and the like, for example, a plasma SiN film (film easy to transmit ultraviolet region light) or BPSG (borophosphosilicate glass) film that has a refractive index of approximately the same as that of the first insulation layer. Here, in the same manner as described above, a first wiring layer that includes the vertical selection line 6 and the intra-layer insulation layer 22 to insulate the wirings is formed. Further, a second wiring layer that includes the readout pulse line 7, vertical signal line 8 and the planarizing film 261 to insulate those-wirings is formed.

Next, as shown in FIG. 7C, a photo-resist film is formed on the first insulation layer 291 and is subjected to patterning to form a reflow film 27 made of the photo-resist film at a corresponding position above the light-receiving sensor portion 2.

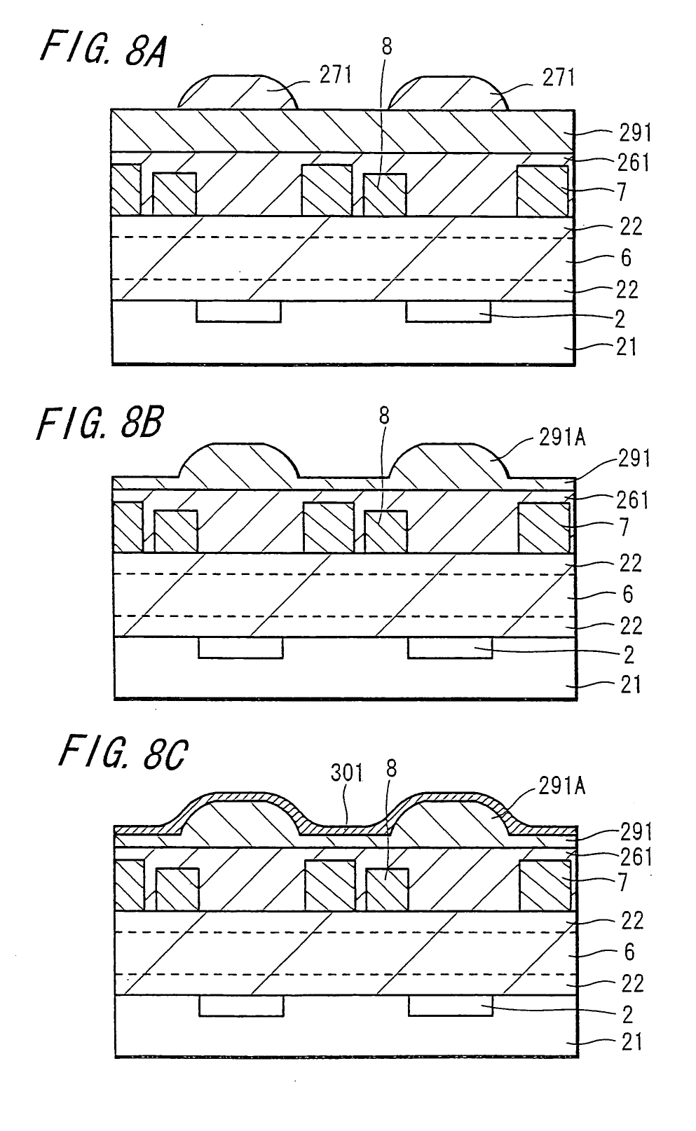

Then, as shown in FIG. 8A, the reflow film 27 is subjected to reflow processing at a required temperature to form a reflow film 271 with a convex surface.

Next, as shown in FIG. 8B, the lower layer first insulation layer 291 with the reflow film 271 having a convex surface is subjected to etching back and the surface shape of the reflow film 271 is transferred to the first insulation layer 291 to form a convex portion 291A on the first insulation layer 291. The position, size, curvature, depth and the like of this convex portion 291A are arbitrarily controlled by the shape of the reflow film 271, the time of etching and the like.

Next, as shown in FIG. 8C, a second insulation layer 301 with a refractive index of approximately the same as that of the first insulation layer 291 is formed on the first insulation layer 291 along the surface shape thereof. The second insulation layer 301 can be formed of a silicon nitride film (P-SiN film) with, for example, a refractive index of approximately 2.0 by a plasma CVD method.

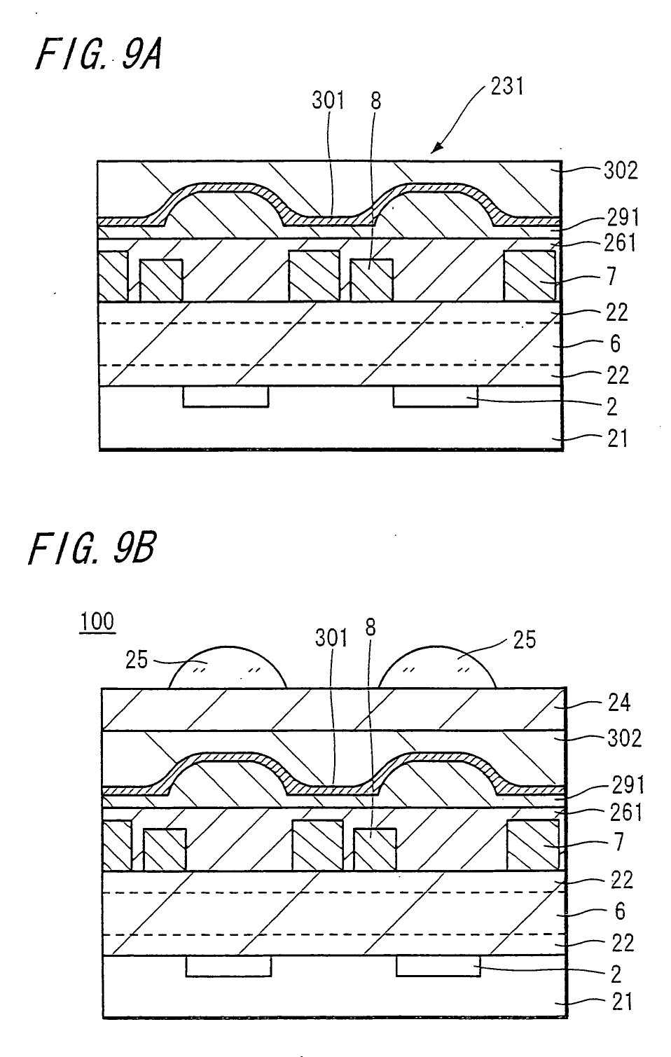

Next, as shown in FIG. 9A, a second planarizing film (insulation layer) 302 with a second refractive index is formed on the second insulation layer 301. The second planarizing film 302 can be formed of an insulation layer with a refractive index of approximately 1.5, for example. The second planarizing film 302 can be formed of a thermosetting acrylic resin film, for example. Accordingly, a single intra-layer condensing lens 231 (convex lens) including the first insulation layer 291 and second insulation layers 301 with a large refractive index and the second planarizing film 302 with a small refractive index is formed in the convex-shaped portion 291A. In this intra-layer condensing lens 231, on the interface between the second planarizing film 302 and the upper surfaces of the first and second insulation layers 291 and 301, light is refracted in the direction condensing, in conjunction with the relative relations between the refractive indices thereof.

Next, as shown in FIG. 9B, a color filter 24 is formed on the second planarizing film 302, and further, an on-chip micro-lens 25 is formed on the color film 24 to obtain an aimed CMOS-type solid-state imaging device 100.

Further, on the interface between the second insulation layer 301 and planarizing film 302, a reflection preventing film with a refractive index between those of both the layers may be formed, and on the interface between the first planarizing film 261 and first insulation layer 291, a reflection preventing film with a refractive index between those of both the layers may be formed.

Since the CMOS-type solid-state imaging device 100 according to this embodiment has a single intra-layer condensing lens, that is, a convex lens 231 in this embodiment, with respect to each light-receiving sensor portion 2, even in a structure where a number of the light shielding patterns, wiring patterns and the like are laminated, incident light can be optimally condensed on the light-receiving sensor portion 2. Also in the case where the uppermost layer wirings 7 and 8 are disposed on both sides of the light-receiving sensor portion 2, since each light-receiving sensor portion 2 has a single intra-layer condensing lens, the light condensing rate can be improved. In addition, being the single intra-layer condensing lens 231 without combining two cylindrical intra-layer condensing lenses makes the structure thereof simplified. Since the wirings 6, 7 and 8 can be formed of metal materials including Al, the reliability of the wiring 6, 7 and 8 can be obtained. Further, since the intra-layer condensing lens 231 on the periphery side of the imaging region is formed biased to the center side of the light-receiving sensor portion 2 with the center of the lens farther away from the center of an imaging region, shading due to the oblique light can be improved. Even when the wirings 7 and 8 are disposed to be asymmetrical with respect to the light-receiving sensor portion 2, the intra-layer condensing lens 231 is formed without being affected by the underlaid wirings, and light is favorably condensed. Consequently, a light condensing rate is improved by a single intra-layer condensing lens with high precision and the CMOS-type solid-state imaging device having high reliability can be provided.

According to the method for manufacturing the CMOS-type solid-state imaging device 100 of this embodiment, the reflow film 271 with a convex surface corresponding to each light-receiving sensor portion 2 is formed on the first insulation layer 291 and the first insulation layer 291 with the reflow film 271 is etched back; as a result, the surface shape of the reflow film, that is, convex surface can be transferred to the first insulation layer 291. After the second insulation layer 301 with a refractive index of approximately the same as that of the first insulation layer .291 (first refractive index) is formed on the first insulation layer 291 along the convex portion 291A, the second planarizing layer 302 with a second refractive index is formed across the whole surface thereof to form the intra-layer condensing lens 231 of a convex lens, so that the single intra-layer condensing lens can easily be formed. Particularly, in the case where part of the uppermost wirings are disposed in parallel on both sides of the light-receiving sensor portion 2 and asymmetrically with respect thereto, the intra-layer condensing lens 231 can be formed with respect to the light-receiving sensor portion 2 without being affected by the underlaid wirings. The shape of the intra-layer condensing lens 231 (the height, position, curvature and the like of the lens) can easily be adjusted by changing the pattern of the reflow film 271 of the photo-resist, etching conditions and the like. Since the high temperature reflow processing is not required, the wirings 6, 7 and 8 can be formed of metal materials including Al. In addition, the center of the intra-layer condensing lens can simply be biased to the center side of the imaging region from the center of the light-receiving sensor portion 2 by only changing the shape pattern of the reflow film 271. Accordingly, as the countermeasure against shading due to oblique light on the periphery of the imaging region, what is called a biased-lens pupil correction method can be applied. As described above, according to the manufacturing method of this embodiment, the intra-layer condensing lens 23 can be formed with precision in the CMOS-type solid-state imaging device.

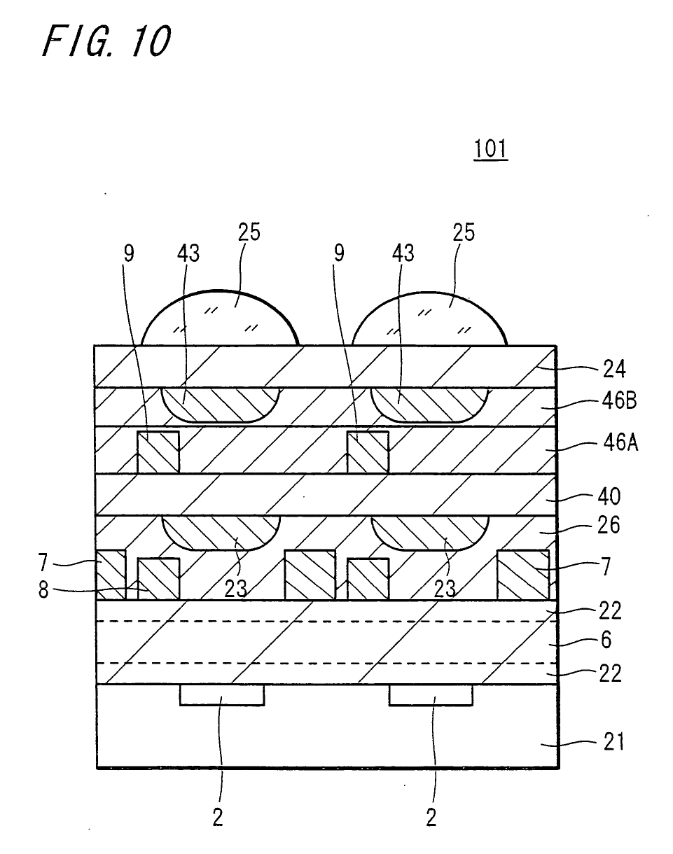

FIG. 10 shows another embodiment of a solid-state imaging device according to the present invention. In this embodiment a plurality of intra-layer lenses are provided in each pixel.

Specifically, a solid-state imaging device 101 according to this embodiment includes: on the semiconductor substrate 21 with the light-receiving sensor portion 2, vertical selection switch element 3 and readout switch element 4 similarly formed as in the above-described FIG. 3, the vertical selection sensor portion 6 of the first-layer wiring and the readout pulse line 7 and vertical signal line 8 of the second-layer wiring are formed through the intra-layer insulation layer 22, and further thereon, the lower layer intra-layer condensing lens 23 is formed corresponding to the position of each light-receiving sensor portion 2 through the intra-layer insulation layer 26. Further, the intra-layer insulation layer 40 is formed, and wirings 9 are formed on the intra-layer insulation layer 40 and then, an upper layer intra-layer condensing lens 43 is formed on an insulation layer 46A covering the wirings 9 to be planarized. The color filter 24 is formed on the upper layer intra-layer condensing lens 43, and the on-chip micro-lens 25 is formed thereon at a position corresponding to each of light-receiving sensor portions 2 and intra-layer condensing lenses 23 and 43. The wirings 9 are disposed such that a wiring 9 of one pixel and a wiring 9 of an adjacent pixel are disposed at positions having difference with respect to distance from the light-receiving sensor portion 2. Here, a first wiring layer including the vertical selection line 6 and the intra-layer insulation layer 22 that insulates this wiring is formed. A second wiring layer including the readout pulse line 7, vertical selection line 8 and insulation layer 26 that insulates those wirings is formed. Further, a third wiring layer including the wiring 9 and insulation layer 46A that insulates this wiring is formed.

In this solid-state imaging device, the wirings 9 are formed further above the vertical signal line 8 and readout pulse line 7, and a concave portion constituting the upper layer intra-layer condensing lens 43 is correspondingly formed above the position between a wiring 9 of one pixel and a wiring 9 of an adjacent pixel. Here, the concave portion of the lower side intra-layer condensing lens is formed on the upper surface of the insulation layer 26 that covers the vertical signal line 8 and readout pulse line 7 to be planarized, while a concave portion of the upper side intra-layer condensing lens is formed on the surface of an insulation layer 46B separately formed on the insulation layer 46A that covers the wirings 9 to be planarized. In the case where the insulation layers 46A and 46B are separately formed, light can be efficiently led to the light-receiving sensor portion 2 by taking advantage of refraction on the interface. On the contrary, in the case where only the insulation layer 26 is used, the structure can be simplified.

In addition, FIG. 10 shows the case where two concave-portion intra-layer lenses are provided; however, a convex intra-layer lens may be included, and the number of the intra-layer lenses may further be increased.

Further, in the case of FIG. 10 where a plurality of intra-layer lenses are provided, as a countermeasure against shading, the more a pixel approaches the periphery of an imaging region, the more biased may the intra-lens be formed toward the center side of the imaging region, if necessary.

The intra-film 40 is provided between the insulation layers 26 and 46A in FIG. 10, which is not necessarily required.

Since a plurality of intra-layer lenses are provided, incident light can be efficiently led to the light-receiving portion by refracting the incident light more times.

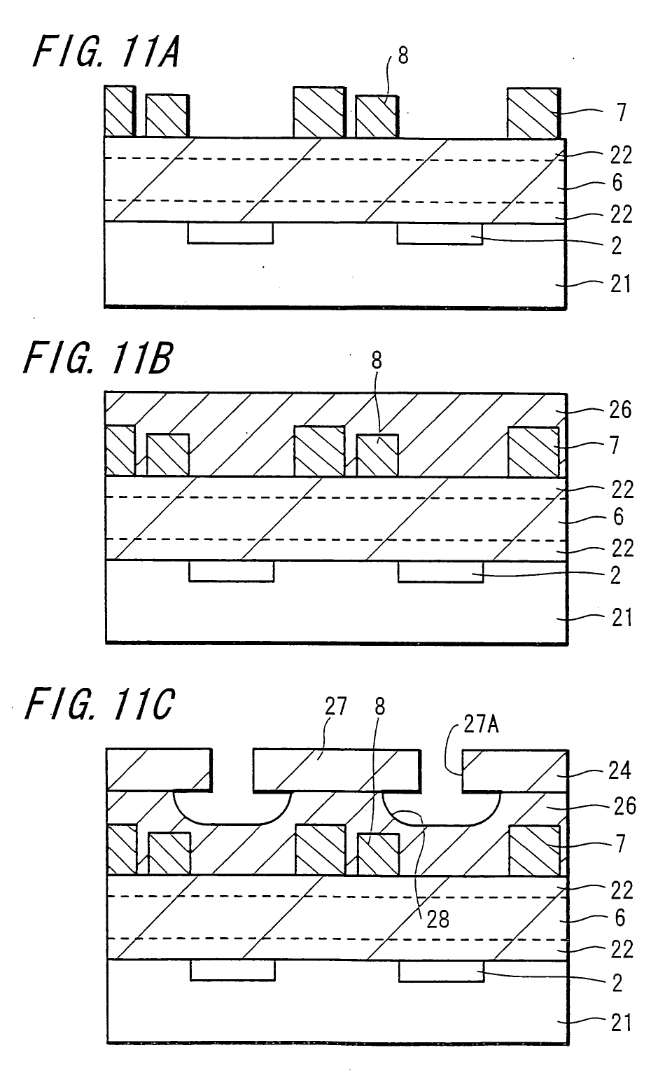

Next, another embodiment of the method for manufacturing the CMOS-type solid-state imaging device 101 according to the above-described embodiment will be explained with reference to FIGS. 11 through 15.

First, as shown in FIG. 11A, after the light-receiving sensor portion 2 constituting what is called a CMOS sensor, vertical selection switch element 3 and readout switch element 4 (not shown) are formed on the semiconductor substrate 21, through the intra-layer insulation layer 22 a light shielding film and wirings that are insulated from each other, in this embodiment, the vertical selection line 6 to be a first-layer wiring extending in one direction on both sides of the light-receiving sensor portion 2 and the readout pulse line 7 and vertical signal line 8 on both sides of the light-receiving sensor portion 2 to be a second-layer wirings group extending in another direction crossing the above-described one direction at right angles are formed. Those vertical selection line 6, readout pulse line 7 and vertical signal line. 8 are formed of metal materials including Al, in this embodiment, Al. In this embodiment, the readout pulse line 7 and vertical signal line 8 to be the second-layer wirings group are, as shown in FIG. 2, asymmetrically formed with respect to the light-receiving sensor portion 2. Therefore, the vertical signal line 8 of a pixel and the readout pulse line 7 of an adjacent pixel are disposed at positions having difference with respect to distance from the light-receiving sensor portion 2.

Next, as shown in FIG. 11B, the first insulation layer 26 with a first refractive index is formed across the whole surface including the readout pulse line 7 and vertical signal line 8, and then, the first insulation layer 26 is planarized. For example, the first insulation layer 26 can be formed by laminating a low temperature CVD film of high density plasma CVD, plasma TEOS or the like, for example, BPSG (borophosphosilicate glass) film. A BPSG film has, as described above, a refractive index of approximately 1.40 to 1.46. The planarizing can be carried out using the CMP (Chemical Mechanical Polishing) method.

Next, as shown in FIG. 11C, a photo-resist film is formed on the first insulation film 26, which is then subjected to patterning such that the opening 27A is formed at a position corresponding to the light-receiving sensor portion 2 to form the resist mask 27. By way of isotropic-etching through the resist mask 27, the first insulation film 26 is selectively etched and removed. Accordingly, the concave portion 28 corresponding to each light-receiving sensor portion 2 is formed in the first insulation layer 26 to form the intra-layer condensing lens. The position, size, curvature, depth and the like of the concave portion 28 are arbitrarily controlled by the opening 27A of the resist mask 27, etching time and the like.

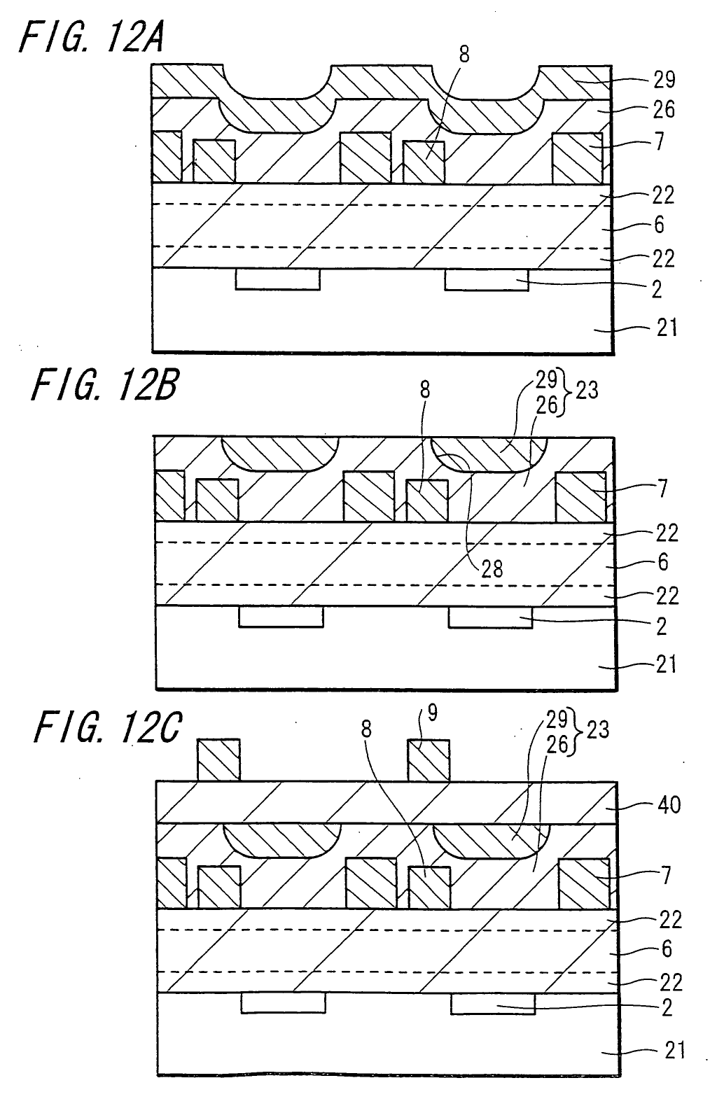

Next, after the resist mask 27 is removed, as shown in FIG. 12A, the second insulation layer 29 with the second refractive index is formed across the whole surface to bury the concave portion 28. The second insulation layer 29 can be formed by laminating a silicon nitride (P—SiN) film using, for example, a plasma CVD method. This silicon nitride film has a refractive index of approximately 2.0.

Next, as shown in FIG. 12B, the second insulation layer 29 is planarized by etch-back or the like. As a result, the lower-layer single intra-layer condensing lens (concave lens) 23 including the first insulation layer 26 with a small refractive index and the second insulation layer 29 with a large refractive index is formed. In this intra-layer condensing lens 23, on the upper interfaces of the planarized second insulation layer 29 and the not-planarized first insulation layer 26, light is refracted in conjunction with the relative relations between the refractive indices thereof.

Next, as shown in FIG. 12C, after the intra-layer insulation layer 40 is formed on the surface of the lower-layer intra-layer condensing lens 23, the wiring 9 is formed, on the intra-layer insulation layer 40.

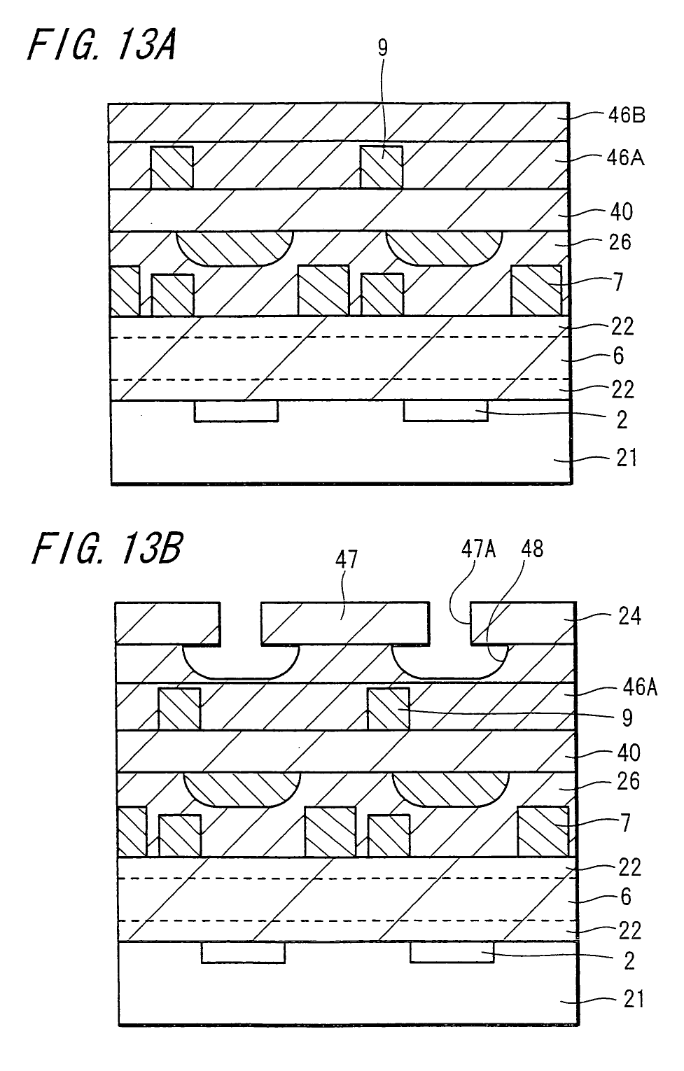

Next, as shown in FIG. 13A, the insulation layer 46A is formed across the whole surface including the wiring 9, and subsequently, the insulation layer 46A is planarized. Further, the insulation layer 46B is formed on the planarized insulation layer 46A and planarized. The insulation layer 46A can be formed by laminating, for example, a low temperature plasma CVD film of high density plasma CVD or plasma TEOS and the like, for example, BPSG (borophosphosilicate glass) film. The BPSG film has a refractive index of approximately 1.40 to 1.46, as described above. The planarizing can be carried out using the CMP (Chemical and Mechanical Polishing) method.

Next, as shown in FIG. 13B, a photo-resist film is formed on the insulation layer 46B, and the photo-resist film is subjected to patterning such that an opening 47A is formed at a position corresponding to each light-receiving sensor portion 2 to form a resist mask 47. Through this resist mask 47, the insulation layer 46B is selectively etched to be removed by isotropic-etching. Accordingly, a concave portion 48 is formed in the insulation layer 46B to form the intra-layer condensing lens corresponding to each light-receiving sensor portion 2. The position, size, curvature, depth and the like of the concave portion 48 can arbitrarily be controlled by an opening 47A of the resist mask 47, etching time and the like.

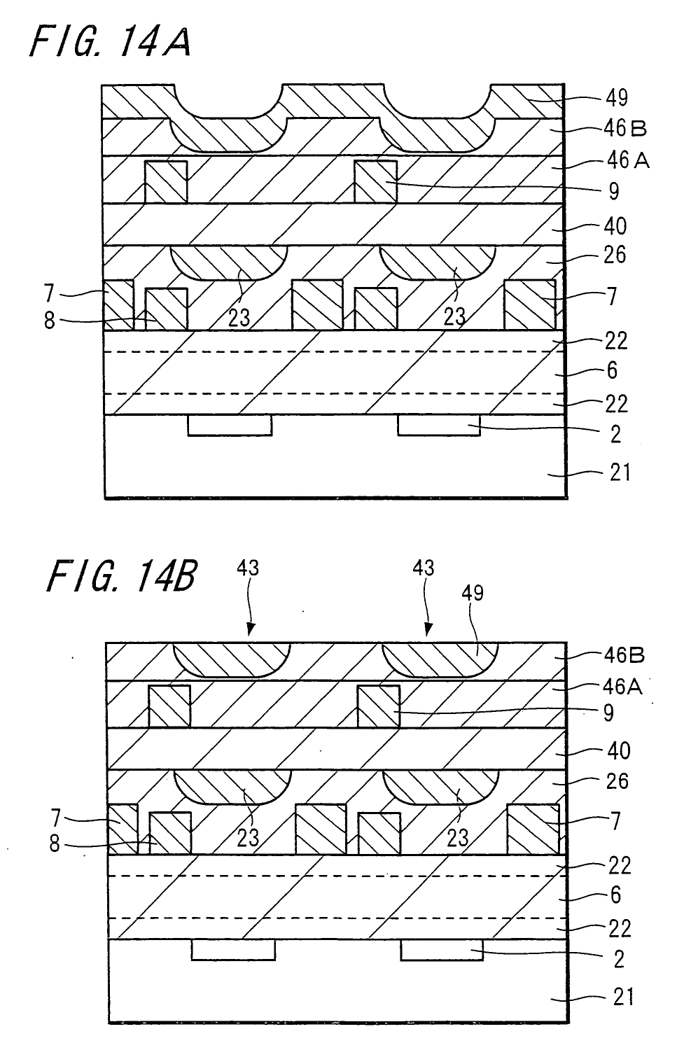

Next, after the resist mask 47 is removed, as shown in FIG. 14A, an insulation layer 49 with a refractive index is formed across the whole surface to bury the concave portion 48. The insulation layer 49 can be formed by laminating a silicon nitride film (P—SiN) using, for example, a plasma CVD method. This silicon nitride film has, as described above, a refractive index of approximately 2.0.

Next, as shown in FIG. 14B, the insulation layer 49 is planarized by etch back and the like. As a result, an upper layer single intra-layer condensing lens (concave lens) 43 including the third insulation layer 46B with a small refractive index and the forth insulation layer 49 with a large refractive index is formed in the concave portion 48. In this upper layer intra-layer condensing lens 43, on the upper interfaces of the planarized forth insulation layer 49 and of the not-planarized third insulation layer 46B, light is refracted in the light condensing direction in conjunction with the relative relations between the refractive indices thereof.

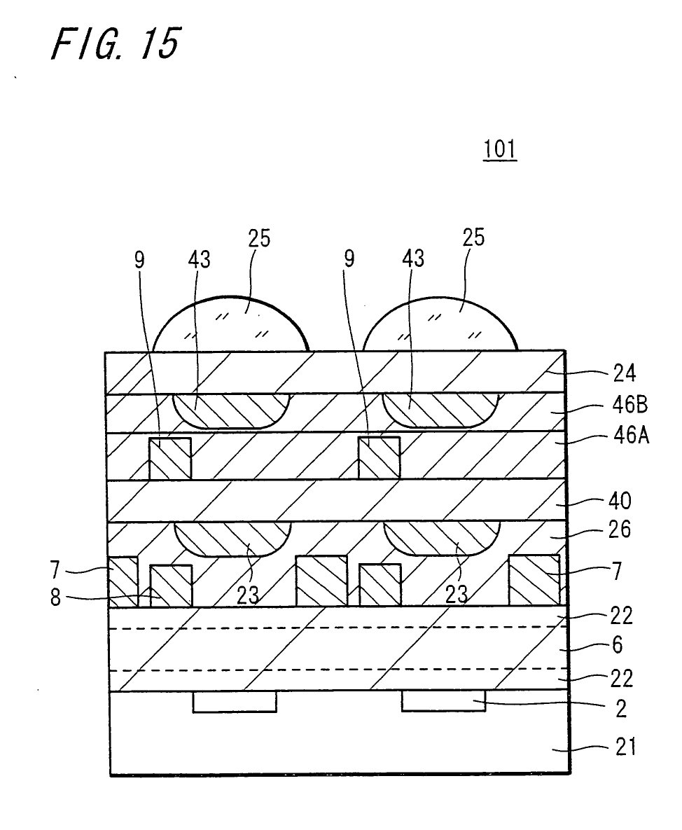

Next, as shown in FIG. 15, the color filter 24 is formed on the above-described planarized upper surface, and further, on-chip micro-lens 25 is formed on the color filter 24, so that the aimed CMOS-type solid-state imaging device 101 is obtained.

Note that in the above embodiment, the lower layer intra-layer condensing lens 32 and upper layer intra-layer condensing lens 43 are formed of insulation layers with the same refractive index; however, other cases may be possible. The intra-layer condensing lenses 23 and 43 can be formed of insulation layers with different refractive indices.

The solid-state imaging device 101 according to this embodiment includes single intra-layer condensing lenses, the concave lenses 23 and 43 in this example, with respect to each light-receiving sensor portion 2, even in the structure in which a number of the light shielding pattern, wiring patterns and the like are laminated, incident light can be optimally condensed on the light-receiving sensor portion 2. Particularly, in this embodiment, by providing the plurality of intra-layer condensing lenses 23 and 43 with respect to each light-receiving sensor portion 2, incident light can be refracted more times to lead the incident light efficiently to the light-receiving sensor portion 2. Moreover, in the same manner as described above, each of the condensing lenses 23 and 43 is a single intra-layer condensing lens without combining two cylindrical lenses, so that the structure of the intra-layer condensing lens is simplified. Since the wirings 6, 7, 8 and 9 can be formed of metal materials including Al, the reliability of the wirings 6, 7, 8 and 9 can be obtained. In addition, since the intra-layer condensing lenses 23 and 43 on the periphery of the imaging region are formed biased to the center side of the light-receiving sensor portion 2 as the center of the lenses approach the periphery, shading due to oblique light can be improved. Even when the wirings 7 and 8 or the wirings 9 are asymmetrically disposed with respect to the light-receiving sensor portion 2, the upper layer and lower layer intra-layer condensing lenses can be formed without being affected by the underlaid wirings, so that light can favorably be condensed. Accordingly, a light condensing rate is improved by a single intra-layer condensing lens with high precision and the CMOS-type solid-state imaging device having high reliability can be provided.

In the method for manufacturing the CMOS-type solid-state imaging device 101 according to this embodiment, a concave portion of a first insulation layer is subjected to isotropic-etching through a resist mask; subsequently, a second insulation layer is provided to form the lower layer intra-layer condensing lens 23; a concave portion of a third insulation layer is similarly subjected to isotropic-etching through a resist mask; and subsequently a forth insulation layer is provided to form the upper layer intra-layer condensing lens 43, so that a plurality of single intra-layer condensing lenses 23 and 43 per pixel can easily be formed. Particularly, when part of the wirings are disposed in parallel on both sides of the light-receiving sensor portion 2 and asymmetrically with respect to the light-receiving sensor portion 2, a plurality of intra-layer condensing lenses can be formed without being affected by underlaid wirings. In addition, as described above, the shape (the height, position, curvature and the like) of the upper and lower layer intra-layer condensing lenses 23 and 43 can easily be adjusted by changing the opening pattern 27A of the resist mask 27, the pattern of the opening 47A of the resist mask 47, etching conditions and the like. Since the reflow processing at a high temperature is not required, wirings 6, 7, 8 and 9 can be formed of metal materials including Al. By only changing the opening patterns of the resist masks 27 and 47, the center of the intra-layer condensing lenses 23 and 43 can be biased to the center side of the imaging region from the center of the light-receiving sensor portion 2. Accordingly, as the countermeasure against shading due to oblique light on the periphery of the imaging region, what is called a biased-lens pupil correction method can be applied.

In the method for manufacturing the CMOS-type solid-state imaging device according to the above-described embodiments, the cases where a pixel has either one or two intra-layer lenses have been shown. However, the same manufacturing method can be applied to a case where a pixel has three intra-layer lenses or more, and a plurality of intra-layer lenses in which concave lenses and convex lenses are combined can also be formed.

Further, although omitted in the above-described explanations, prior to the above-described manufacturing processes, such processes of: forming a charge readout transistor to read out the charge from a light-receiving portion, forming a gate electrode to operate the charge readout transistor and forming a planarizing layer which covers the gate electrode to be planarized are included in most cases.

Furthermore, the present invention can be applied to a CMOS-type solid-state imaging device in which wirings integrally formed around each light-receiving sensor portion are disposed in the uppermost layer to also shield light. In that case, the uppermost layer wirings are often connected to the source of predetermined voltage.

In addition, in the above-described explanations, the vertical signal line 8 of one pixel as well as the readout pulse line 7 of an adjacent pixel are made to be wirings disposed at positions having difference with respect to distance from the light-receiving sensor portion; however, without being limited to this structure, a drain signal line, various transistor-driving pulse lines and the like may be used as those wirings, and not the wirings of pixels adjacent to each other but ones in which two wirings belonging to the same pixel may be used.

Further, a “solid-state imaging device” is not limited to the above cases, where only the structures used in the above-described explanations are included, but indicates a device in which a necessary optical system, an imaging chip, a signal processing chip and the like are integrated to be a module.

As described above, a solid-state imaging device according to the present invention is what is called a CMOS-type solid-state imaging device having pixels each including a light-receiving sensor portion and a MOS transistor. In the CMOS-type solid-state imaging device of the present invention, an intra-layer condensing lens is formed corresponding to each light-receiving sensor portion, so that light can optimally be condensed on the light-receiving sensor portion even when a number of a shielding pattern, wiring pattern and the like are laminated. Furthermore, each being a single intra-layer condensing lens makes the structure thereof simplified, resulting in high reliability thereof.

According to the method for manufacturing a solid-state imaging device of the present invention, a concave portion is formed at a position corresponding to each light-receiving sensor portion after a first insulation layer with a first refractive index formed on a semiconductor region where a pixel is formed is selectively removed by isotropic-etching through a resist mask, so that the size, position, curvature and the like of the concave portion can be arbitrarily set. Subsequently, a second insulation layer with a second refractive index is formed in the concave portion to form an intra-layer condensing lens, so that the height and size, position, curvature and the like of the concave portion can be optimized. In addition, the intra-layer condensing lens can be formed without being affected by under layers. Therefore, it is possible to form the intra-layer condensing lens capable of optimally condensing light.

According to a method for manufacturing a solid-state imaging device of the present invention, a first insulation layer with a first refractive index is etched back with a reflow film having a convexly curved surface formed corresponding to a light-receiving sensor portion to transfer the shape of the reflow film onto the first insulation layer and a planarizing film with a second refractive index is formed to make an intra-layer condensing lens, so that the height and size, position, curvature and the like of the lens can be optimized. Further, the intra-layer condensing lens can be formed without being affected by under layers. Therefore, it is possible to form the intra-layer condensing lens capable of optimally condensing light.

1. A Solid-state imaging device comprising:
a plurality of pixels each including a light-receiving portion, a wiring layer including a plurality of wirings and a plurality of lenses formed above said light-receiving portions, wherein at least one of said plurality of lenses is an intra-layer lens including a first layer with a concave portion formed by etching and a second layer formed to bury said concave portion.

2. A solid-state imaging device according to claim 1, wherein said wiring layer includes at least a first wiring and a second wiring formed on both sides of said light-receiving portion; said first wiring and second wiring are differently positioned with respect to the distance from said light-receiving portion; and said intra-layer lens is positioned between said first wiring and said second wiring.

3. A solid-state imaging device according to claim 2, wherein said first wiring and second wiring are integrally formed and are connected to a predetermined voltage source.

4. A solid-state imaging device according to claim 1, wherein each of said pixels includes a charge readout transistor and a planarizing film which covers a gate electrode of said charge readout transistor to be planarized, and said plurality of wirings are formed above said planarizing film.

5. A solid-state imaging device according to claim 1, wherein said first layer is an insulation layer formed to directly cover said plurality of wirings to constitute said wiring layer.

6. A solid-state imaging device according to claim 1, wherein said first layer is an insulation layer formed on said wiring layer.

7. A solid-state imaging device according to claim 1, wherein in a pixel farther away from the center of an imaging region, the center of said intra-layer lens is formed, being biased from above the center of said light-receiving portion to the center side of said imaging region.

8. A solid-state imaging device according to claim 1, wherein at least one of said plurality of lenses is an on-chip lens formed above said intra-layer lens.

9. A solid-state imaging device comprising:
a plurality of pixels each including a light-receiving portion, a wiring layer including a plurality of wirings and a plurality of lenses formed above said light-receiving portion, wherein at least one of said plurality of lenses is an intra-layer lens including a first layer with a convex portion formed by etching and a second layer formed to cover said convex portion.

10. A solid-state imaging device according to claim 9, wherein said wiring layer includes at least a first wiring and a second wiring formed on both sides of said light-receiving portion; said first wiring and said second wiring are differently positioned with respect to the distance from said light-receiving portion; and said intra-layer lens is positioned between said first wiring and said second wiring.

11. A solid-state imaging device according to claim 9, further comprising a third layer formed between said first and said second layers to cover said convex portion.

12. A method for manufacturing a solid-state imaging device comprising the steps of:
forming a plurality of light-receiving portions on the surface of a substrate; forming wirings on both sides of each of said light-receiving portions; forming a first insulation layer having a first refractive index; etching said first insulation layer by using an etching mask and forming a concave portion above each of said light-receiving portions; and forming a second insulation layer with a second refractive index to bury said concave portion.

13. A method for manufacturing a solid-state imaging device according to claim 12, further comprising the steps of: prior to the step of forming said wirings,
forming a charge readout transistor; forming a gate electrode to operate said charge readout transistor; and forming a planarizing film which covers said gate electrode to be planarized, wherein said wirings and said concave portions are formed above said planarizing film.

14. A method for manufacturing a solid-state imaging device comprising the steps of:
forming a plurality of light-receiving portions on the surface of a substrate; forming wirings on both sides of each of said light-receiving portions; forming a first insulation layer with a first refractive index; forming a reflow film with a convex surface at a position corresponding to the position of said light-receiving portions above said first insulation layer; etching back said first insulation layer with said reflow film and transferring said convex surface onto said first insulation layer; and forming a second insulation layer with a second refractive index on said first insulation layer.

15. A method for manufacturing a solid-state imaging device according to claim 14 further comprising the step of:
forming a third insulation layer to cover said convex surface of said first insulation layer prior to the step of forming said second insulation layer.

16. A solid-state imaging device comprising:
a plurality of pixels arranged each including a light-receiving portion and a MOS transistor, wherein a single intra-layer lens is formed corresponding to each of said light-receiving portions.

17. A solid-state imaging device according to claim 16, wherein part of uppermost layer wirings formed above said light-receiving portions are positioned on both sides of each of said light-receiving portions.

18. A solid-state imaging device according to claim 16, wherein the center of said intra-lens is biased to the center side of an imaging region from the center of said light-receiving portion, when approaching the periphery of the imaging region.

19. A solid-state imaging device according to claim 16, wherein part of the uppermost layer wirings positioned on both sides of said light-receiving portion are asymmetrically disposed with respect to said light-receiving portion, and said intra-lenses are formed without being affected by said asymmetrical wirings.

20. A solid-state imaging device according to claim 16, wherein said wirings are formed of metallic materials including Al.

21. A method for manufacturing a solid-state imaging device comprising the steps of:
forming wirings on a semi-conductor region in which a plurality of pixels each including a light-receiving portion and a MOS transistor are arranged through an insulation layer with the light-receiving portion in between; forming a first insulation layer with a first refractive index across the whole surface thereof; selectively removing said first insulation layer with a etching mask by isotropic-etching at a position corresponding to said light-receiving portion to form a concave portion corresponding to each light-receiving portion; forming a second insulation layer with a second refractive index across the whole surface including said concave portion; and planarizing said second insulation layer and making the second insulation layer remain within said concave portion to form a single intra-lens using said first and second insulation layers.

22. A method for manufacturing a solid-state imaging device comprising the steps of:
forming wirings on a semi-conductor region in which a plurality of pixels each including a light-receiving portion and a MOS transistor are arranged through an insulation layer with the light-receiving portion in between; forming a first insulation layer with a first refractive index across the whole surface thereof; forming a reflow film with a convexly curved surface at a position corresponding to the respective light-receiving portions on said first insulation layer; etching back said first insulation layer with said reflow film to transfer said convexly curved surface onto said first insulation layer; and forming a planarizing film with a second refractive index on said first insulation layer to form a single intra-layer lens including said first insulation layer and said planarizing film.
